(19) United States
(12) Patent Application Publication
(10) Pub. No.: US 2006/0043070 A1
(43) Pub. Date: Mar. 2, 2006

(54) High temperature functioning stripper for cured difficult to remove photoresist coatings

(76) Inventor: John C. Moore, Camarillo, CA (US)

Correspondence Address: GENERAL CHEMICAL PERFORMANCE PRODUCTS LLC., 90 EAST HALSEY ROAD, PARSIPPANY, NJ, 07054, US

(21) Appl. No.: 10/930,096

(22) Filed: Aug. 31, 2004

(51) Int. Cl. B44C 1/22; H01L 21/302

(52) U.S. Cl. 216/83; 438/725; 216/96

(57) ABSTRACT

A chemical stripping solvent composition is provided for removing cured polymeric isoprene from inorganic substrates comprising normal and isoparaffins exhibiting a high flash point and a sulfonic acid dissolving system. The stripping composition comprises a blend of chemistries, designed to operate at high temperature processing conditions without attack to sensitive metals. The invention will remove fully cured negative-tone isoprene-based photoresist at temperatures equal to or beyond 100° C. Isoprene polymer in the presence of certain cross-linking photoinitiators will cure to a smooth rubber and highly chemically resistant framework. This material is used to produce patterns, which become the basis for depositing microcircuits in semiconductor manufacturing. Upon exposure to the invention, the cured polymer will begin to breakdown, allowing the residue to be rinsed away with IPA or water. A corrosion inhibitor that is proven to be high temperature stable is added to protect metals. Removal rates vary depending upon the thickness of the resist and the condition which it was exposed during the process. Heat and agitation will improve the removal process.

This invention relates to chemical strippers for removing cured photoresist polymeric layers such as negative-tone isoprene-based photoresist coatings. More particularly, the invention relates to strippers that have a high flash point and operates at temperatures in excess of 100° C. to exhibit a higher removal rate as compared to known industry standards. The stripper of the present invention comprises a blend of high temperature normal paraffins or isoparaffins such as those which exhibit boiling fractions in the range between 220-315° C. and a flash point of between 90-130° C. and are available for example, under the brand names Norpar® 13 or 15 and Isopar® M or V, respectively, from Exxon Mobil Corporation (Norpar® and Isopar® are registered trademarks of Exxon Mobil Corporation).

A dissolving system composed of a blend of saturated normal or iso-aliphatic solvents having a high solubility for 1.3-butadiene chemistry, typical of synthetic rubber and similar straight and cyclized isoprenes is employed. The invention employs a stripper for “isoprene rubber” chemistry that is the basis for many photoresists used in semiconductor manufacturing. However, the invention is not limited thereto. The sulfonic acid may include alkyl benzene sulfonic acid or dodecylbenzene sulfonic acid, typical of the precursor varieties to linear alkyl benzene sulfonate (LAS) surfactant.

A suitable corrosion inhibitor, e.g., 2-mercaptobenzothiazole (MBT), is added to afford protection for soft metal substrates, such as aluminum, from the corrosive effects of free sulfuric acid and related materials as a result of the sulfonic acid. The invention offers stability during processing at high temperature where most organic materials will breakdown and be rendered unusable or become more corrosive to metals. When used in conjunction with metals at given exposure times, the chemistry is found to be safe with even the softest of metals, such as aluminum and will maintain this metal protection over time approaching a factor of 10 times the normal process period. The stripper of the invention is easily rinsed with hydrophilic chemistries such as isopropanol and/or water. The invention has been found to be a substantial benefit in the area of semiconductor wafer processing.

### BACKGROUND OF THE INVENTION

Reference is made to my co-pending U.S. patent application Ser. No. 10/745,079 filed Dec. 23, 2003, the disclosure of which is incorporated herein by reference.

Isoprene polymer, in the presence of certain cross-linking photoinitiators, will cure to a smooth rubber and highly chemically resistant framework. The cured polymeric material is used to produce patterns (masks) which become the basis for etching or depositing metal, leading to microcircuits in semiconductor manufacturing. At the completion of the process, the mask is removed utilizing the novel stripping composition of the invention. Upon contact with the stripper, the cured polymeric mask will chemically breakdown, and in turn, may be readily rinsed away while preserving metal integrity.

During the manufacture of semiconductor microcircuits, various inorganic substrates such as single and polycrystalline silicon, hybrid semiconductors such as gallium arsenide, and metals, are coated with a polymeric organic substance which forms a resist mask after undergoing a photolithographic process. The polymeric resist mask is used to protect selected areas of the substrate surface, e.g., silicon, silicon dioxide, or aluminum, etc., from the action of chemicals in both wet (solution) and dry (plasma) forms. The exposed areas of the substrate may carry out a desired etch (removal) or deposition (addition) process. Following completion of this operation and after subsequent rinsing or conditioning, it is necessary that the resist mask and any application post-etch residue be removed to permit essential finishing operations. Upon removal of the mask, specific micro-etched or deposited patterns are left behind. The masking and patterning processes are repeated several times to produce layered microcircuits that comprise the final semiconductor device. Each step requires complete resist stripping and cleaning, to ensure that the final form device is produced at good yields and performs satisfactorily.

Organic masking agents comprise many sorts of photoresists. The present invention is concerned in particular with systems operable at relatively high temperatures of the order of 100° C. and higher. One of the more tenacious polymers is a negative-tone variety that is hydrophobic (non-polar), described as a biazide/cyclized isoprene (rubber) system. Cyclized isoprene is preferred over conventional natural rubber and other polymerized isoprenes due to its more rigid character and reduced solubility. The isoprene polymer is linear, a product of straight-chain Ziegler-Natta polymerization, making it a good candidate for between-chain crosslinking. The isoprene photoresist will react to light and initiate a photochemical reaction. Upon exposure to ultraviolet light of a specific frequency, the azide undergoes free-radical generation and crosslinks between the isoprene chains. The result is a rigid polymer network that incorporates the azide crosslinker between the chains.

The exposed system is less soluble than the unexposed material. The unexposed material is dissolved and rinsed away (developed) from the exposed, leaving behind a negative image as compared to the pattern in which light had traveled. Once the pattern is produced, metal may be either etched or deposited by electroplating (wet) or plasma processing (dry) as described earlier. One practice used in the industry to produce defined metal circuits is by a technique called “lift-off.” Following the establishment of a resist pattern exhibiting a negative-tone profile, metal is deposited throughout by plasma processing. Now the resist is coated with metal as well as down into the channels onto the exposed substrate within the pattern, which exhibits a “negative slope.” The process of stripping involves removing unwanted metal along with the resist pattern. The strip method involves solvent molecules penetrating exposed resist from the side at the negative slope profile. As the solvent penetrates, the resist begins to swell, dissolve, and move, causing the unwanted metal to “lift-off.” Once the metal and resist enters the bulk chemical, it can then be filtered-out and allow the stripper to be reused repeatedly. After the resist is stripped and metal is lifted off and rinsed away, what is left behind are the metal lines that were originally deposited within the resist pattern. It is therefore desired to carryout this stripping process at a range of temperatures, including high temperature, to enhance performance and bath life for difficult to remove resists without sacrifice to metal integrity.

It is recognized by the prior art that stripping compositions have been less than satisfactory and/or have the disadvantage of being unstable at higher temperatures. Additionally, some strippers present unacceptable toxicity and/or pollution problems from the disposal of such compounds, such as phenol, cresol, and chlorinated hydrocarbons. Other known prior art for removing polymeric organic substances that include inorganic compounds are not suitable such as, aqueous sulfuric acid compositions containing a significant amount of fluoride ion to reduce metallic dulling and corrosion, as exemplified in U.S. Pat. No. 3,932,130. Some photoresist strippers require the presence of fluoride ion stabilizers to prevent metallic corrosion and operate at elevated temperatures. Although these strippers may provide value to industrial applications, often they are deemed to be too aggressive for semiconductor devices.

The efficiency and selectivity of a stripper is also desirable. There is a need, accordingly, for improved stripping compositions, which will remove the polymeric organic substance from the coated inorganic substrate without corroding, dissolving or dulling the surface of the metallic circuitry, or chemically altering the inorganic substrate.

This invention provides a novel tool for the semiconductor manufacturing industry that permits the stripping of difficult to remove photoresists such as negative-tone isoprene photoresists at relatively high processing temperatures equal to or exceeding 100° C. The invention offers a benefit over the prior art, as disclosed in U.S. Pat. Nos. 4,165,294; 4,992,108 and 6,261,735 and the aforementioned pending U.S. patent application Ser. No. 10/745,079 that deals with the removal of isoprene resist coatings. The invention provides an improved safe chemical stripper for difficult to remove fully cured photoresist coatings that have heretofore resisted efficient complete dissolution and removal while maintaining metal and substrate integrity.

It is, accordingly, the objective of this invention to provide a relatively high temperature operative stripper and process which is employed to thoroughly and selectively penetrate and dissolve fully-cured resist coatings utilizing a novel composition that contains a solvent that rapidly penetrates and swells the relatively unsoluble cured cross-linked photoresist coating and wherein the strong acid of the stripper composition selectively hydrolizes the photoresist molecule making the resist soluble and readily removed and without corroding the metal substrate.

### SUMMARY OF THE INVENTION

In accordance with this invention, a high temperature stable stripping composition for removing polymeric organic substances from an inorganic substrate is provided. The stripping composition comprises a blend of non-polar normal and/or isoparaffins having a resulting flash point at greater than 100° C. and effectively dissolve and facilitate the removal of fully cured and cross-linked polymeric layers such as cured negative tone isoprene photoresists. Using a sulfonic acid having a high solubility in hydrocarbon solvents to maintain a strong organo-acidic environment and preferably a metal inhibitor to corrosive environments, the system is brought to high temperatures equal to or greater than 100° C. where the solvent rapidly penetrates and swells the cross-linked polymer while the strong acid selectively hydrolyzes the molecule without corroding metals, making the resist soluble in the invention where it may then be removed by simple rinsing. The dissolving system is composed of a blend of saturated cyclic-hydrocarbon solvents having a high solubility for 1,3 butadiene and similar straight and cyclized isoprenes, typical of synthetic rubber.

The invention is particularly advantageous for use in dissolving cured negative-tone isoprene based photoresist layers. The “isoprene rubber” chemistry is used as the basis for many photoresists used in semiconductor manufacturing. The sulfonic acid may include an alkyl benzene sulfonic acid of varying molecular weights, common precursors to linear alkyl benzene sulfonate (LAS) surfactants. A non-degradable corrosion inhibitor is preferably added to maintain protection for soft metals such as aluminum, copper, bronze, etc. from the corrosive effects of free sulfuric acid and related materials as a result of the sulfonic acid. 2-mercaptobenzothiazole (MBT) is a preferred corrosion inhibitor. The invention offers stability during processing at high temperatures where most organic materials that are exposed to corrosives will breakdown and be rendered unusable or begin to degrade metals.

What is noteworthy is the heat and corrosive stable inhibitor. 2-mercaptobenzothiazole (MBT) will not degrade at high temperatures in the sulfonic acid chemistry, provided that the solvents of choice are saturated (i.e., no double or triple bonded atoms). Using UV/VIS spectroscopy in the range of 200-400 nm, it is found that one of MBT's peaks is resolved broadly at 325 nm. When MBT is used to inhibit corrosion in the stripper, this signature region is found to be stable at temperatures greater than or equal to 110° C. for periods of time in excess of 20 hours, provided the solvent system is composed only of saturated hydrocarbons. In cases where unsaturated hydrocarbons have been tested, the MBT is shown to rearrange with a significant reduction or elimination of the peak noted at 325 nm, moving into the deep UV. These tests have shown that MBT, a preferred corrosion inhibitor for preserving metals during the stripping process, is preserved at high temperatures for long periods of time only when saturated hydrocarbons are the solvents of choice.

During processing, the invention immediately penetrates into the isoprene resist and begins to swell and dissolve the resist away. Processing times vary depending upon the cure conditions of the isoprene. Full-cure isoprene may be easily dissolved and removed upon exposure of the invention at 100° C. in 1-2 minutes. Extreme temperature cure isoprene resists taken to 150° C. or greater to result in a more polymerized and dense state, yet may still be dissolved and removed at the same conditions in 5-15 minutes. As with most chemical systems, raising the processing temperature will result in a more aggressive stripping condition, and conversely, reduce the process time, improve performance, and increase bath life. Therefore, it is desired to operate at high temperatures. Rinsing of the invention may be carried out in an aggressive DI water wash. Due to the high surfactancy of the LAS-based sulfonic acid, the invention will emulsify and rinse away. For substrates, which may be sensitive to reduced pH due to the presence of the acid, IPA is recommended as an alternative.

### DETAILED DESCRIPTION OF THE INVENTION

The present invention provides a novel stripping composition, which quickly and effectively removes polymeric organic substances from inorganic substrates, from metallic, non-metallic and metallized non-metallic substrates and includes methods of using the composition. The stripping composition of the invention comprises normal and/or isoparaffin solvents (A & B), a suitable linear alkyl benzene sulfonate (LAS)-based acid such as mono-, di-, or tri-alkyl benzene sulfonic acid (C), and a corrosion inhibitor (D), of suitable formulations and include compositions within weight proportions set forth herein below in Table 1.

TABLE 1
Preferred weight percentage formulations.

| Item | Chemical | % (Wt./wt.) |
|---|---|---|
| A | Isopar ® V isoparaffin | 30-55 |
| B | Isopar ® M isoparaffin | 20-40 |
| C | Linear Alkyl Benzene Sulfonic Acid | 20-40 |
| D | Corrosion Inhibitor | 0.5-1.5 |

Note:
Isopar ® is a registered trade name of Exxon Mobil Corporation.

The preferred normal paraffins are those which exhibit boiling fractions in the range between 220-280° C. and a flash point of between 95-120° C.

The preferred isoparaffins are those which exhibit boiling fractions in the range between 220-315° C. and a flash point of between 90-130° C.

Although suitable linear alkyl benzene sulfonate (LAS)-based acids such as mono-, di-, or tri-alkyl benzene sulfonic acid may be used, the preferred LAS-acid is dodecylbenzene sulfonic acid (DDBSA).

The preferred corrosion inhibitor found to be stable in a saturated hydrocarbon matrix with the identified sulfonic acid is 2-Mercaptobenzothiazole (MBT).

The invention dissolves and removes fully cured polymeric layers such as isoprene resist coatings at various cure levels and is particularly effective and stable at temperatures exceeding 100° C.

The invention comprises stripping compositions that contain specialty organic acids blended with a solvent system that is selected to exhibit high solubility and elevated temperature performance and stability. Although isoprene-based resists are known to require the stripper be taken to high temperatures for relatively long periods of time, the non-polar character of the solvent system of the invention is effective in expeditiously and thoroughly dissolving and removing the resists.

For example, fully cured cross-linked isoprene resists that have been post-baked at temperatures up to and including 150° C., may be dissolved and removed by using the stripping composition in a period of less than 15 minutes at a temperature of ≦90° C. and preferably below 5 minutes at ≦120° C. The invention's capacity to operate at high temperatures, above 100° C., enables the achievement of a high bath life as compared to other products designed for similar stripping compositions. Other stripping products are not able to operate at such high temperatures without significant exposure to flammability due to the majority of such competing mixtures to exhibit flash points less than the invention. Further, the active ingredients provide excellent dissolution and offer surfactancy such that the solvent system of the invention may be easily rinsed with alcohol or emulsified in DI water. Metals such as aluminum are observed to be safe based upon exposure tests taken to a factor of up to 10 times the normal processing time.

The stripper of the invention is stable at a variety of temperatures. It will maintain a homogeneous and stable mix at high temperatures. The invention is usable and stable against discoloration at temperatures above 120° C., relative to various prior art strippers that darken at or near 100° C.

It is observed in the application of the dissolving (stripper) system of the invention that cured isoprenes which are taken to excessive temperatures of ≧150° C. or may be cured onto non-conventional substrates (i.e., aluminum or polyimide) that some of the “rubber” character of the isoprene may be lost yielding a more dense material. The product, accordingly, would likely require the stripper of the invention in dissolving and removing such dense specimens of the kind, which heretofore require more aggressive chemistries to penetrate the matrix and cause dissolution. In cases such as these, it is likely that increased temperatures will be needed.

The stripper of the invention is hydrophobic which maximizes dissolution of the isoprene, while minimizing effects on any hydrophilic materials present. Most noteworthy with such a hydrophobe (i.e., hydrocarbon solvents) is it's reduced solution conductivity. Galvanic corrosion (i.e., metal attack) is directly dependent upon solution conductivity. When considering galvanic corrosion in solutions of hydrocarbons similar to this invention, this system is expected to have a reduced prevalence of corrosion as compared to hydrophilic solvents that conduct at a greater rate.

The following specific examples further illustrate the invention. It will be understood, however, that although these examples may describe in detail certain preferred operating conditions of the invention, they are given primarily for purposes of illustration and the invention in its broader aspects is not limited thereto.

### EXAMPLE 1

### Demonstration of Cured Isoprene Resist Stripping

Silicon wafers containing patterned resist present around metal topographies representing both chemical and plasma etch processing are employed. The resist curing was effected by a post exposure bake (PEB) in an oven or hot plate. The stripping process in all cases was noted to be completed in ≦5 min @ 120° C. The strip process was followed by a IPA and DI water rinse. Observations were conducted on an optical microscope and a scanning electron microscope (SEM). The optical scope included Nomarski® surface attenuating objectives to 1000× with a digital camera attachment. The SEM was performed on selected areas to show complete removal with preservation of the metal. Results of these tests are shown in Table 2.

TABLE 2
Exposure of isoprene resist patterns to solvating stripper of the invention.

| # | Resist | (Pos/Neg) | Supplier | Ash (Y/N) | Resist Cure | Strip Process | Results |
|---|---|---|---|---|---|---|---|
| 1 | SC-180 | Neg | Arch | N | PEB 135 C. 30 min | ≦120 C., 5 min | Clean |
| 2 | SC-180 | Neg | Arch | Y | PEB 135 C. 30 min | ≦120 C., 5 min | Clean |
| 3 | HNR 120 | Neg | Arch | N | PEB 135 C. 30 min | ≦120 C., 5 min | Clean |
| 4 | HNR 120 | Neg | Arch | Y | PEB 135 C. 30 min | ≦120 C., 5 min | Clean |
| 5 | SC-180 | Neg | Arch | N | PEB 150 C. 20 min | ≦120 C., 5 min | Clean |
| 6 | Fuji 43 | Neg | Fujifilm | N | PEB 150 C. 30 min | ≦120 C., 5 min | Clean |
| 7 | PCBPR | Pos | Everlight | N | PEB 105 C. 40 min | ≦120 C., 5 min | Clean |

### EXAMPLE 2

Application of the stripper of the invention to cured negative-tone isoprene and positive-tone acrylic resists. Silicon wafers containing patterned resist present around metal topographies representing both chemical and plasma etch processing. Resist curing as given represent post exposure bake (PEB) in an oven or hot plate. The strip process in all cases was noted to be completed in 5-15 min @ 120° C. The strip process was followed by a IPA and DI water rinse. Observations were conducted on an optical microscope and a scanning electron microscope (SEM). The optical scope included Nomarski® surface attenuating objectives to 1000× with a digital camera attachment. The SEM was performed on selected areas to show complete removal with preservation of the metal. Results of these tests are shown in Table 3.

TABLE 3
Description of results after exposure of resist patterns to invention.

| # | Resist | (Pos/Neg) | Supplier | Ash (Y/N) | Resist Cure | Strip Process | Results |
|---|---|---|---|---|---|---|---|
| 1 | SC-450 | Neg | Arch | N | 135 C. 30 min | ≦120 C., 5 min | Not Clean |
| 2 | SC-450 | Neg | Arch | N | 135 C. 30 min | ≦120 C., 15 min | Clean |
| 3 | SC-180 | Neg | Arch | N | 135 C. 30 min | ≦120 C., ≦5 min | Clean |
| 4 | SPR700 | Pos | Arch | N | 150 C. 30 min | ≦120 C., 15 min | Not Clean |
| 5 | SPR700 | Pos | Arch | Y | 105 C. 40 min | ≦120 C., ≦5 min | Clean |

Although the invention has been described in terms of specific embodiments, it will be apparent that one skilled in the art can substitute other known variants, and embodiments without departing from the essence of the invention. Accordingly, the invention is to be limited only by the scope of the appended claims.

What is claimed:

1. A high temperature stable liquid solvating composition for removing cured cross linked polymeric photoresist surface layers from an inorganic substrate comprising a blend of:
(a) from about 30 to about 55 weight percent of a normal and/or isoparaffins that exhibit boiling fractions in the range between 220-280° C. and a flash point of between 95-120° C.,
(b) about 20 to about 40 weight percent of an iso-paraffin of the formula which exhibits boiling fractions in the range between 220-315° C. and a flash point of between 90-130° C., and
(c) About 20 to about 40 weight percent of an alkylbenzene sulfonic acid.

2. A liquid solvating composition of claim 1, which includes also from about 0.5 to about 1.5 weight percent of a corrosion inhibitor.

3. The composition of claim 1 wherein (a) is present in amounts of about 35 to about 45 weight percent, (b) and (c) are present in amounts of about 25 to about 35 weight percent.

4. The composition of claim 1 wherein (c) is dodecylbenzene sulfonic acid (DDBSA).

5. The composition of claim 2 wherein the corrosion inhibitor is 2-mercaptobenzothiazole (MBT).

6. In a method for removing cured cross-linked polymeric layers from an inorganic substrate the improvement characterized in the materials to be removed is contacted with the stripping solvent of claim 1 at temperatures in excess of 100° C. for a period of time sufficient to remove said substance.

7. In a method for removing full-cure isoprene negative photoresists from an inorganic substrate the improvement is characterized in that the isoprene resist to be removed is contacted with the stripping solvent of claim 1 at a temperature not less than about 90° C. for a period of time sufficient to remove said substance.

8. In a method for removing full-cure isoprene negative photoresists from an inorganic substrate the improvement is characterized in that the isoprene resist to be removed is contacted with the stripping solvent of claim 2 at temperatures in the range of from about 100° C. to about 120° C. for a period of time sufficient to remove said substance.

9. In a method for removing full-cure isoprene negative photoresists from an inorganic substrate the improvement is characterized in that the isoprene resist to be removed is contacted with the stripping solvent of claim 5 at temperatures in the range of from about 100° C. to about 120° C. for a period of time sufficient to remove said substance.
